(19) United States
(12) Patent Application Publication
(10) Pub. No.: US 2016/0042829 A1
(43) Pub. Date: Feb. 11, 2016

(54) Transparent Conductive Film and Fabrication Method Thereof, Display Substrate and Display Device

(71) Applicants: BOE TECHNOLOGY GROUP CO., LTD., Beijing (CN); BEIJING BOE DISPLAY TECHNOLOGY CO., LTD., Beijing (CN)

(72) Inventors: Tengteng HU, Beijing (CN); Jinyu REN, Beijing (CN); Yongzhi SONG, Beijing (CN)

(21) Appl. No.: 14/421,643

(22) PCT Filed: Jun. 30, 2014
(86) PCT No.: PCT/CN2014/081121

§ 371 Date: Feb. 13, 2015

(30) Foreign Application Priority Data
Oct. 21, 2013 (CN) 201310495576.5

(51) Int. Cl. H01B 1/08; C23C 14/28; C23C 14/02

(52) U.S. Cl. CPC H01B 1/08; C23C 14/021; C23C 14/28

(57) ABSTRACT

The present invention provides a transparent conductive film, a fabrication method thereof, a display substrate and a display device. The transparent conductive film includes a seed film layer and a nano-wire film layer, and the fabrication method includes: forming the seed film layer on the substrate by adopting a pulsed laser deposition method, and forming the nano-wire film layer on the seed film layer by adopting the pulsed laser deposition method. The nano-wire film layer has a particular one-dimensional nano-wire structure, thereby increasing the light transmittance of the transparent conductive film to improve the utilization rate of light energy, and quickly collecting charges and directly transmitting the same along one-dimensional channels formed by the one-dimensional nano-wires to improve the collection efficiency of the charges.

### FIELD OF THE INVENTION

The present invention relates to the field of display technology, and particularly relates to a transparent conductive film and a fabrication method thereof, a display substrate and a display device.

### BACKGROUND OF THE INVENTION

Transparent conductive films (such as a common electrode and a pixel electrode) in a display panel are required to not only have good capabilities of transmitting and storing charges but also allow light from a backlight to penetrate therethrough as much as possible during display, in order to obtain a better display effect.

In a traditional display panel, the transparent conductive film is usually made of indium tin oxide material. The material comprises many small and dense micro crystalline grains, in which a large number of grain boundaries (i.e., contact interfaces between crystalline grains with the same structure but different orientations) and dangling bonds (i.e., unsaturated bonds, which are formed by unpaired electrons on surfaces of atoms) are formed. These grain boundaries may cracked to smaller ones in an annealing treatment process, thus resulting in more grain boundaries. As the grain boundaries and the dangling bonds have imperfections, the imperfections will lead to decreased diffusion lengths of the electrons, and therefore, the probability of recombination of electrons and holes is increased, and a carrier recombination center is formed, thus influencing transmission and collection efficiencies of electrons. Moreover, the grain boundaries may have a scattering effect on photoelectrons, which will lead to an increased charging time of the display panel and a reduced response speed.

Meanwhile, the transparent conductive film made of the indium tin oxide material has a dense micro crystalline grain structure, and it thus has a certain negative effect on the light transmittance of the display panel. As a result, the light transmittance of the display panel is generally less than 10%, and the utilization rate of light energy is low.

In addition, due to the limited reserves of indium element materials in the nature, it is urgent to develop a substitute material for forming the transparent conductive film to replace the indium tin oxide material, so as to further improve the yield and reduce the product cost.

### SUMMARY OF THE INVENTION

In view of the above-mentioned technical problems in the prior art, the present invention provides a transparent conductive film and a fabrication method thereof, a display substrate and a display device. The transparent conductive film is fabricated by using a pulsed laser deposition method and has a particular one-dimensional nano-wire structure, thereby improving the light transmittance of the transparent conductive film so as to improve the utilization rate of light energy. Moreover, the transparent conductive film can quickly collect charges and directly transmit the same along one-dimensional channels formed by the one-dimensional nano-wires so as to improve the collection efficiency of the charges. For the display substrate adopting the transparent conductive film, the light transmittance thereof is greatly improved; moreover, the charging time is significantly shortened and the response speed is greatly improved.

The present invention provides a fabrication method of a transparent conductive film, wherein the transparent conductive film is fabricated on a substrate, and the fabrication method includes:
step S1: forming a seed film layer on the substrate by adopting a pulsed laser deposition method, wherein the seed film layer includes uniformly distributed nano-crystalline grains; and
step S2: forming a nano-wire film layer on the seed film layer by adopting the pulsed laser deposition method, wherein the nano-wire film layer includes a plurality of one-dimensional nano-wires arranged in parallel.

Preferably, the step S1 includes:
step S11: performing ultrasonic cleaning for the substrate by using an organic solution;
step S12: drying the substrate; and
step S13: depositing and forming the seed film layer on the substrate in an oxygen atmosphere and a room temperature environment of a deposition chamber by the pulsed laser deposition method.

Preferably, the step S2 includes:
step S21: depositing and forming the nano-wire film layer on the seed film layer in an oxygen atmosphere of the deposition chamber by the pulsed laser deposition method.

Preferably, the step S11 includes: cleaning the substrate ultrasonically in an acetone solution and an ethanol solution, each for 30-60 minutes;
the step S13 includes: filling oxygen in the vacuum deposition chamber so that the pressure in the deposition chamber would be within a range of 6-10 Pa;
the step S21 includes: filling oxygen in the deposition chamber so that the pressure in the deposition chamber would be within a range of 25-35 Pa;
the purity of the oxygen filled in the deposition chamber in the step S13 and the step S21 is 99.9%-99.9999%.

Preferably, in the pulsed laser deposition method, a pulsed laser transmitter is arranged outside the deposition chamber; a focusing lens is arranged between the pulsed laser transmitter and the deposition chamber; the deposition chamber is provided with a transparent quartz window; a target platform and a base platform are arranged oppositely in the deposition chamber; a target material is arranged on the target platform; the focus of the focusing lens, the center of the quartz window and the center of the target material are located in the same straight line; the substrate is arranged on the base platform and is parallel to the target material, and the step S13 and/or step S21 further includes: adjusting the distance between the focusing lens and the quartz window so as to focus the focusing lens on the target material, and adjusting the distance between the target material and the substrate to be 4.5-5.5 cm; and moreover, setting the target platform and the base platform to rotate at the same rotating speed of 5 r/min.

Preferably, in the pulsed laser deposition method, the frequency of laser pulses is 9-11 Hz, the number of the laser pulses is 5000-7000, and the energy of a single laser pulse is 248-252 mJ.

Preferably, the target material adopts a transition metal oxide with a purity of 99.99%-99.9999%, and the transition metal oxide includes zinc oxide, tin oxide or titanium oxide.

The present invention further provides a transparent conductive film, including a seed film layer, which includes uniformly distributed nano-crystalline grains, and a nano-wire film layer, which includes a plurality of one-dimensional nano-wires and is arranged on the seed film layer.

Preferably, each one of the plurality of one-dimensional nano-wires is extended on the seed film layer in a one-dimensional manner and is arranged in parallel to each other to form the nano-wire film layer, and the diameter of each one of the plurality of one-dimensional nano-wires is 60-80 nm.

Preferably, an included angle between each one of the plurality of one-dimensional nano-wires and the seed film layer is 80-90 degrees.

Preferably, the seed film layer and the nano-wire film layer are made of a transition metal oxide, and the transition metal oxide includes zinc oxide, tin oxide or titanium oxide.

Preferably, the thickness of the seed film layer is 20-50 nm, and the thickness of the nano-wire film layer is 2-3 μm.

The present invention further provides a display substrate, including the above-mentioned transparent conductive film.

Preferably, the transparent conductive film is used as a common electrode and/or a pixel electrode of the display substrate.

The present invention further provides a display device, including the above-mentioned display substrate.

The present invention has the following beneficial effects: the transparent conductive film fabricated by using the pulsed laser deposition method has the particular one-dimensional nano-wire structure, thereby improving the light transmittance of the transparent conductive film so as to improve the utilization rate of light energy, and thereby quickly collecting charges and directly transmitting the same along one-dimensional channels formed by the one-dimensional nano-wires so as to improve the collection efficiency of the charges. For the display substrate adopting the transparent conductive film, the light transmittance thereof is greatly improved; moreover, the charging time is significantly shortened and the response speed is greatly improved; meanwhile, the transition metal oxide may be used for replacing the indium material to form the transparent conductive film, which improves the yield and reduces the product cost.

### BRIEF DESCRIPTION OF THE DRAWINGS

FIG. 1 is a schematic diagram of a structure of a transparent conductive film in Embodiment 1 of the present invention;

FIG. 2 is a schematic diagram of a structure of a color filter substrate in Embodiment 2 of the present invention;

FIG. 3 is a schematic diagram of a structure of an array substrate in Embodiment 3 of the present invention;

FIG. 4 is a morphological structure diagram of a nano-wire film layer fabricated in an oxygen partial pressure environment of 30 Pa;

FIG. 5 is a morphological structure diagram of a nano-wire film layer fabricated in an oxygen partial pressure environment of 20 Pa;

FIG. 6 is a morphological structure diagram of a nano-wire film layer fabricated in an oxygen partial pressure environment of 40 Pa.

### REFERENCE NUMERALS

1. seed film layer; 11. nano-crystalline grain; 2. nano-wire film layer; 21. one-dimensional nano-wire; 3. first glass substrate; 4. black matrix layer; 5. color filter layer; 6. planarization layer; 7. common electrode; 8. columnar spacer; 9. pixel electrode; 10. second glass substrate; 12. gate electrode; 13. gate insulation layer; 14. active area; 15. source electrode; 16. drain electrode; 17. passivation layer.

### DETAILED DESCRIPTION OF THE EMBODIMENTS

In order that those skilled in the art may better understand the technical solutions of the present invention, a further detailed description of a transparent conductive film and a fabrication method thereof, a display substrate and a display device in the present invention will be given below in combination with the accompanying drawings and specific embodiments.

### Embodiment 1

This embodiment provides a transparent conductive film, as shown in FIG. 1, the transparent conductive film includes a seed film layer 1 and a nano-wire film layer 2. The seed film layer 1 includes uniformly distributed nano-crystalline grains 11, the nano-wire film layer 2 includes a plurality of one-dimensional nano-wires 21, and the nano-wire film layer 2 is arranged on the seed film layer 1.

Specifically, each one of the plurality of one-dimensional nano-wires 21 is extended on the seed film layer 1 in a one-dimensional manner and is arranged in parallel to each other to form the nano-wire film layer 2, and the included angle between each one-dimensional nano-wire 21 and the seed film layer 1 is 80-90 degrees. The diameter of each one-dimensional nano-wire 21 is 60-80 nm. The thickness of the seed film layer 1 is 20-50 nm, and the thickness of the nano-wire film layer 2 comprising the plurality of one-dimensional nano-wires 21 is 2-3 μm.

The seed film layer 1 has the uniformly distributed nano-crystalline grain structures, which is favorable to forming crystal nuclei. Based on the crystal nuclei, it is facilitated to form the nano-wire film layer 2 having the plurality of one-dimensional nano-wires and having a uniform structure and good morphology. Since the nano-wire film layer 2 has the plurality of one-dimensional nano-wires arranged in parallel, the film layer has a uniform porosity, as a result, the light transmittance of the transparent conductive film is greatly improved, and then the utilization rate of light energy is improved; moreover, each one-dimensional nano-wire forms one one-dimensional transmission channel for photogenerated electrons. Therefore, charges are collected quickly and are transmitted directly along the one-dimensional channels, thus improving the collection efficiency of the charges, and also, the grain boundaries are reduced, thus reducing the possibility of losing the photoelectrons due to scattering by the grain boundaries.

Preferably, the seed film layer 1 and the nano-wire film layer 2 are made of a transition metal oxide material, and the transition metal oxide preferably includes zinc oxide, tin oxide or titanium oxide. By replacing the commonly used indium tin oxide material with the transition metal oxide , the selectable range of the materials of the transparent conductive film is further expanded, and accordingly, the indium element material can be replaced by the substitute material, thus improving the yield and reducing the product cost; and meanwhile, by adopting the transition metal oxide, the photoelectric property of the transparent conductive film can be improved.

This embodiment further provides a fabrication method of the above-mentioned transparent conductive film, wherein the transparent conductive film is fabricated on a substrate, and the fabrication method includes steps as follows.

At step S1, a seed film layer is formed on the substrate by adopting a pulsed laser deposition method, wherein the seed film layer includes uniformly distributed nano-crystalline grains

It should be noted that, the above-mentioned substrate may be a substrate, such as a glass substrate or a polymer substrate, and may also be other substrate formed with other film layer(s) and pattern(s).

The step specifically includes:
step S11: performing ultrasonic cleaning for the substrate by using an organic solution.

In this step, the substrate is ultrasonically cleaned in an acetone solution and an ethanol solution, each for 30-60 minutes. Namely, the substrate is ultrasonically cleaned in the acetone solution for a period of time, for example, 30 minutes, and then the substrate is ultrasonically cleaned in the ethanol solution for a period of time, for example, 30 minutes, in order to keep the high cleanness of the substrate to facilitate the subsequent deposition and firm attachment of a film layer.

At step S12, the substrate is dried, and then the dried substrate is arranged in a deposition chamber.

In this embodiment, a pulsed laser transmitter is arranged outside the deposition chamber; a focusing lens is arranged between the pulsed laser transmitter and the deposition chamber; the deposition chamber is provided with a transparent quartz window; a target platform and a base platform, are arranged oppositely in the deposition chamber; and a target material is arranged on the target platform; the focus of the focusing lens, the center of the quartz window and the center of the target material are located in the same straight line; the substrate is arranged on the base platform and is parallel to the target material.

At step S13, the seed film layer is deposited and formed on the substrate in an oxygen atmosphere and a room temperature environment of a deposition chamber by using the pulsed laser deposition method.

In this embodiment, the deposition chamber may be firstly vacuumized to 5.0*10⁻⁸ Pa to 5.0*10⁻⁴ Pa, and meanwhile, inside of the deposition chamber is kept at the room temperature. For example, the deposition chamber may be firstly vacuumized to be lower than 5 Pa by a mechanical pump, and then is vacuumized to 5.0*10⁻⁴ Pa or below by a molecular pump. Subsequently, oxygen with a purity of 99.9%-99.9999% is filled in the deposition chamber to change the pressure in the deposition chamber to be 6-10 Pa. More preferably, oxygen with a purity of 99.99% is filled in the deposition chamber to change the pressure in the deposition chamber to 8 Pa. In addition, in this embodiment, a deposition thickness of the seed film layer is 20-50 nm.

In this step, the distance between the focusing lens and the quartz window may be adjusted to focus the focusing lens on the target material, and the distance between the target material and the substrate may also be adjusted to be 4.5-5.5 cm, and the distance preferably is 5 cm; in addition, the target platform and the base platform may be set to rotate at the same rotating speed, and preferably rotate at the rotating speed of 5 r/min.

In the pulsed laser deposition method, the frequency of laser pulses is 9-11 Hz and is preferably 10 Hz; the number of the laser pulses is 5000-7000 and is preferably 6000; the energy of a single laser pulse is 248-252 mJ and is preferably 250 mJ. A transition metal oxide with a purity of 99.99%-99.9999% is used as the target material, and the preferred purity of the transition metal oxide is 99.99%; preferably, the transition metal oxide includes zinc oxide, tin oxide or titanium oxide.

The pulsed laser deposition is performed under the above-mentioned process conditions, which facilitates the formation of the crystal nuclei, thus it can be ensured that the formed seed film layer has uniformly distributed nano-crystalline grain structures, so as to facilitate the subsequent formation of a nano-wire film layer.

At step S2, a nano-wire film layer is formed on the seed film layer by adopting a pulsed laser deposition method, wherein the nano-wire film layer includes a plurality of one-dimensional nano-wires arranged in parallel.

This step specifically includes:
step S21: forming the nano-wire film layer on the seed film layer in an oxygen atmosphere of the deposition chamber by the pulsed laser deposition method.

This step includes: filling oxygen with a purity of 99.9%-99.9999% in the deposition chamber to change the pressure in the deposition chamber to be 25-35 Pa.

In this step, preferably, oxygen with a purity of 99.9% is filled in the deposition chamber to change the pressure in the deposition chamber to be 30 Pa.

In addition, preferably, an included angle between each one of the plurality of one-dimensional nano-wires arranged in parallel and the seed film layer is 80-90 degrees, and the thickness of the nano-wire film layer is 2-3 μm.

In this step, the distance between the focusing lens and the quartz window is adjusted to focus the focusing lens on the target material, and the distance between the target material and the substrate is adjusted to be 4.5-5.5 cm, and the distance preferably is 5 cm; the target platform and the base platform are set to rotate at the same rotating speed, and preferably rotate at the rotating speed of 5 r/min.

In the pulsed laser deposition method, the frequency of laser pulses is 9-11 Hz and is preferably 10 Hz; the number of the laser pulses is 5000-7000 and is preferably 6000; the energy of a single laser pulse is 248-252 mJ and is preferably 250 mJ. A transition metal oxide with a purity of 99.99%-99.9999% is used as the target material, and the preferred purity of the transition metal oxide is 99.99%; the transition metal oxide includes zinc oxide, tin oxide or titanium oxide.

Under the above-mentioned process conditions, it can be ensured that the nano-wire film layer grows approximately vertically on the basis of the crystal nuclei in the seed film layer, which improves the density and arrangement directionality of the one-dimensional nano-wires in the nano-wire film layer and ensure the nano-wire film layer to have a plurality of one-dimensional nano-wires arranged in parallel.

It should be noted that, in the process of forming the nano-wire film layer by adopting the pulsed laser deposition method, the size of the oxygen partial pressure plays a crucial role, because the oxygen partial pressure directly influences the mean free path of metal oxide particles. An overlarge oxygen partial pressure will lead to decreased free path of the particles, when the free path of the particles is smaller than the distance between the substrate and the target material, in a process of sputtering the particles from the surface of the target material to the substrate, the particles will collide with the oxygen molecules for once or multiple times to have reduced energy, or form an atomic cluster with a larger particle, thus causing a rough surface of the film; when the oxygen partial pressure is too low, the number of the particles arriving at the substrate is reduced, thus influencing the deposition rate and the film forming quality.

In this embodiment, when forming the nano-wire film layer, high-purity oxygen of 30 Pa is preferably filled in the deposition chamber. The oxygen partial pressure of 30 Pa is appropriate, the collision probability of the particles sputtered by laser ablation (i.e., laser deposition) is small in the process of being transmitted to the surface of the substrate, the particle flow rate is desirable, and as a result, more particles can arrive at the surface of the seed film layer with relatively large kinetic energy. The particles arriving at the surface of the seed film layer are apt to move to the positions where the crystal nuclei are formed and then continuously absorb the source material, as a result, the particles are stacked to form orderly one-dimensional linear nanostructures by fusion. The morphological structure of the nano-wire film layer generated at this oxygen partial pressure is as shown in FIG. 4, the nano-wire film layer has obvious one-dimensional morphology, an obvious backbone structure and a moderate porosity, and therefore the light transmittance of the transparent conductive film and the transmission rate of the photogenerated electrons can be greatly improved.

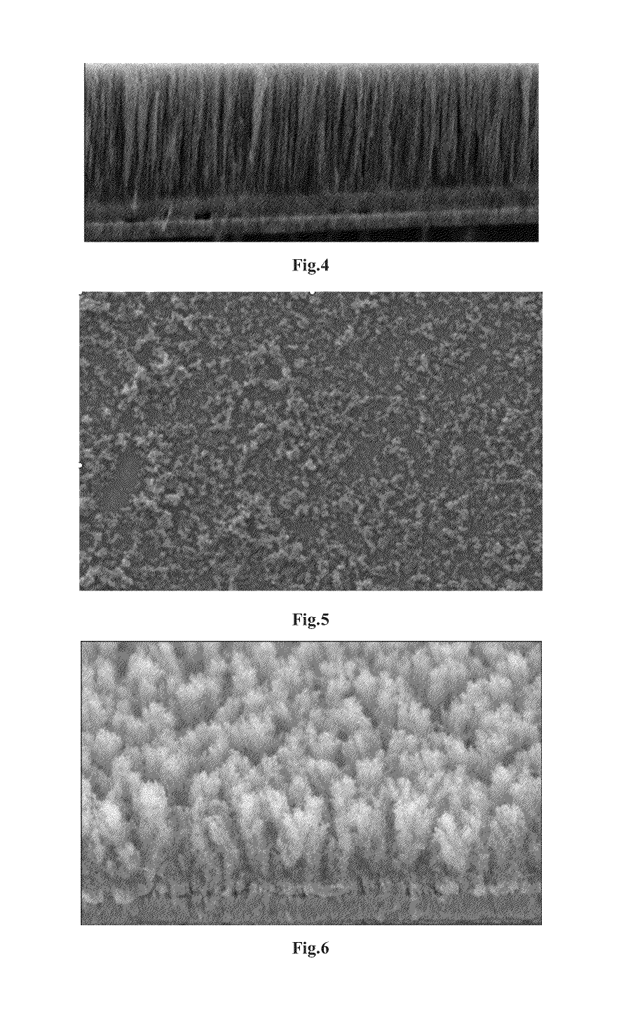

Compared to the above-mentioned preferred oxygen partial pressure, when forming the nano-wire film layer, if high-purity oxygen of 20 Pa is filled in the deposition chamber, a nano-wire film layer having a sparse nano-particle structure may be formed only, and a nano-wire film layer having a one-dimensional nano-wire structure approximately perpendicular to the seed film layer cannot be formed, therefore the nano-wire film layer of this particle structure is not suitable for serving as the transparent conductive film, and the morphological structure diagram of the nano-wire film layer generated at the oxygen partial pressure condition of 20 Pa is shown in FIG. 5. In addition, if high-purity oxygen of 40 Pa is filled in the deposition chamber, the morphological structure of a generated nano-wire film layer is as shown in FIG. 6, it can be seen that, with the increase of the oxygen partial pressure, the morphology of the nano-wire film layer changes significantly. Due to the increase of the oxygen partial pressure, the rate of the sputtered particles is reduced, accordingly, the collision and combination probability of the sputtered particles is increased when being transmitted to the surface of the substrate, and as a result, the sputtered particles are deposited on the surface of the seed film layer in larger particles. Since the kinetic energy is small, the particles are difficult to move in the surface of the seed film layer, in this way, the deposition of the particles is basically random, and a typical dendritical structure is thus formed. This structure has a higher porosity and lacks obvious backbone, the loose multi-branch structure will cause the photogenerated electrons to suffer the scattering effect of a large amount of grain boundaries in the process of being transmitted and separated, which reduces the photoelectric energy, and then influences the photoelectric property of the transparent conductive film. Therefore, the nano-wire film layer of this dendritical structure is not suitable for serving as the transparent conductive film.

### Embodiment 2

This embodiment provides a display substrate, including the transparent conductive film in Embodiment 1. The display substrate in this embodiment is a color filter substrate.

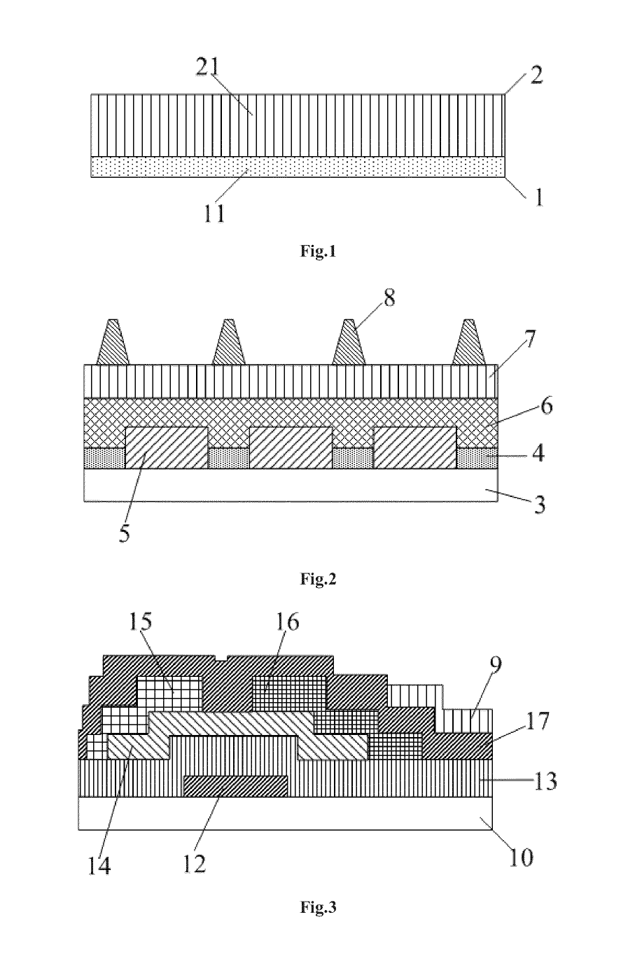

As shown in FIG. 2, the transparent conductive film is used as a common electrode 7 in the color filter substrate.

In this embodiment, the color filter substrate further includes: a first glass substrate 3, black matrix layers 4, color filter layers 5, a planarization layer 6 and columnar spacers 8. The black matrix layers 4 and the color filter layers 5 are alternately arranged on the first glass substrate 3 and in the same layer, and then the planarization layer 6, the common electrode 7 and the columnar spacer 8 are sequentially arranged on the black matrix layers 4 and the color filter layers 5 arranged in the same layer.

Wherein, the surface of the planarization layer 6 is smooth, which is beneficial for the formation and firm attachment of the common electrode 7.

Since the transparent common electrode 7 having a one-dimensional nano-wire structure is arranged in the color filter substrate, the light transmittance of the color filter substrate is greatly improved, and thus the light transmittance of the entire display panel is improved; meanwhile, since the one-dimensional nano-wire structure forms one-dimensional transmission channels for photogenerated electrons, charges may be quickly collected and directly transmitted along the one-dimensional channels, thus shortening the charging time of the display substrate and improving the response speed thereof. In addition, the common electrode is made of a transition metal oxide, which improves the yield and lowers the cost of the display substrate.

In the fabrication method of the above-mentioned color filter substrate, the common electrode 7 is fabricated by using the fabrication method of the transparent conductive film in Embodiment 1.

The fabrication method of the color filter substrate specifically includes:
step S31: forming patterns including the alternate black matrix layers and the color filter layers on the first glass substrate by adopting a patterning process, and then forming the planarization layer on the first glass substrate with the black matrix layers and the color filter layers formed thereon;
step S32: forming the common electrode having a plurality of one-dimensional nano-wires on the first glass substrate subjected to step S31 by adopting a pulsed laser deposition method; and
step S33: forming a pattern including the columnar spacers on the first glass substrate subjected to step S32 by adopting a patterning process.

Here, the patterning process, which is the same as the traditional patterning process, includes photoresist coating, mask plate exposing, developing, etching, baking and other steps, and will not be repeated redundantly herein.

The color filter substrate provided by the embodiment of the present invention further includes an electrostatic shielding layer (not shown in the figure) arranged on a back surface (i.e., the other side of the first glass substrate opposite to the color filter layers) of the color filter substrate, and a transparent conductive film may be used as the electrostatic shield layer. The transparent conductive film may be the transparent conductive film provided by Embodiment 1 and is formed by the fabrication method provided by Embodiment 1.

The display substrate in this embodiment is applicable to a liquid crystal display device or an OLED display device of TN (Twisted Nematic) mode or VA (Vertical Alignment) mode.

### Embodiment 3

This embodiment provides a display substrate, which differs from Embodiment 2 in that, the display substrate in this embodiment is an array substrate. As shown in FIG. 3, the array substrate includes the transparent conductive film in Embodiment 1.

The transparent conductive film may be used as a pixel electrode 9 arranged in the array substrate.

In this embodiment, the array substrate further includes: a second glass substrate 10, and a gate electrode 12, a gate insulation layer 13, an active area 14, a source electrode 15 and a drain electrode 16 arranged in the same layer at intervals, and a passivation layer 17, which are sequentially arranged on the second glass substrate 10. The pixel electrode 9 is arranged on the passivation layer 17 and is connected with the drain electrode 16 through a via hole (not shown in FIG. 3) formed in the passivation layer 17.

Since the transparent pixel electrode 9 of a one-dimensional nano-wire structure is arranged in the array substrate, the light transmittance of the array substrate is greatly improved, thus the light transmittance of the entire display panel is improved; meanwhile, since the one-dimensional nano-wire structure forms one-dimensional transmission channels for photogenerated electrons, charges may be quickly collected and directly transmitted along the one-dimensional channels, thus shortening the charging time of the display substrate and improving the response speed thereof. In addition, the pixel electrode is made of a transition metal oxide, which improves the yield and lowers the cost of the display substrate.

In the fabrication method of the above-mentioned array substrate, the pixel electrode is fabricated by using the fabrication method of the transparent conductive film in Embodiment 1.

The fabrication method of the array substrate specifically includes:
step S41: sequentially forming a pattern including the gate electrode, the gate insulation layer, a pattern including the active area, a pattern including the source electrode and the drain electrode, and the passivation layer on the second glass substrate by adopting a patterning process and a deposition process for multiple times; and
step S42: forming the pixel electrode having the one-dimensional nano-wire structure on the second glass substrate subjected to step S31 by adopting a pulsed laser deposition method.

In this embodiment, the patterning process is the same as the traditional patterning process, and will not be repeated redundantly herein.

The array substrate in this embodiment is applicable to a liquid crystal display device or an OLED display device of TN (Twisted Nematic) mode or VA (Vertical Alignment) mode.

### Embodiment 4

This embodiment provides a display substrate, which differs from Embodiment 2 or 3 in that, the display substrate in this embodiment is formed by assembling a color filter substrate and an array substrate, and both of the color filter substrate and the array substrate include transparent conductive films.

The transparent conductive films are used as a common electrode and a pixel electrode, wherein the common electrode is arranged in the color filter substrate, and the pixel electrode is arranged in the array substrate.

In the display substrate of this embodiment, the other structures of the color filter substrate are the same as those in Embodiment 2, the other structures of the array substrate are the same as those in Embodiment 3, and will not be repeated redundantly herein.

Here, the common electrode and the pixel electrode are respectively fabricated by using the fabrication method of the transparent conductive film in Embodiment 1.

It should be noted that, the display substrate in the present invention refers to any substrate with a display function or for achieving the display function, the display substrate may be a separated array substrate, color filter substrate or opposite substrate, or may be one formed by assembling the array substrate and the color filter substrate or the opposite substrate.

### Embodiment 5

This embodiment provides a display substrate, and the display substrate in this embodiment is an array substrate. Different from the embodiments 2-4, the array substrate includes a common electrode and a pixel electrode made of transparent conductive films.

The specific structure of the array substrate is as follows: based on the structure of the array substrate in Embodiment 3, the common electrode and the pixel electrode are sequentially arranged on a passivation layer, or are sequentially arranged on the passivation layer in a reverse sequence; the common electrode and the pixel electrode are isolated from each other by an insulation layer.

In this embodiment, the common electrode and the pixel electrode are respectively fabricated by using the fabrication method of the transparent conductive film in Embodiment 1, and will not be repeated redundantly herein.

The array substrate in the embodiment is applicable to a liquid crystal display device of ADS (Advanced Super Dimension Switch) mode.

### Embodiment 6

This embodiment provides a display device, including the display substrate in any one of Embodiments 2-5.

The display device may be any product or component with a display function, such as a liquid crystal panel, electronic paper, an OLED panel, a mobile phone, a tablet computer, a television, a display, a notebook computer, a digital photo frame, a navigator, etc.

The present invention has the following beneficial effects: the transparent conductive film fabricated by using the pulsed laser deposition method has the particular one-dimensional nano-wire structure, thereby improving the light transmittance of the transparent conductive film to improve the utilization rate of light energy, and quickly collecting charges and directly transmitting the same along the one-dimensional channels formed by the one-dimensional nano-wires to improve the collection efficiency of the charges. For the display substrate adopting the transparent conductive film, the light transmittance thereof is greatly improved; moreover, the charging time is significantly shortened and the response speed is greatly improved; meanwhile, the transition metal oxide may be used for replacing the indium material, which improves the yield and reduces the product cost.

It may be understood that, the foregoing embodiments are merely exemplary embodiments used for illustrating the principle of the present invention, but the present invention is not limited hereto. Those of ordinary skill in the art may make various variations and improvements without departing from the spirit and essence of the present invention, and these variations and improvements shall fall within the protection scope of the present invention.

1-20. (canceled)

21. A fabrication method of a transparent conductive film fabricated on a substrate, wherein the fabrication method comprises:
step S1: forming a seed film layer on the substrate by adopting a pulsed laser deposition method, wherein the seed film layer comprises uniformly distributed nano-crystalline grains; and
step S2: forming a nano-wire film layer on the seed film layer by adopting the pulsed laser deposition method, wherein the nano-wire film layer comprises a plurality of one-dimensional nano-wires arranged in parallel.

22. The fabrication method of claim 21, wherein the step S1 comprises:
step S11: performing ultrasonic cleaning for the substrate by using an organic solution;
step S12: drying the substrate; and
step S13: depositing and forming the seed film layer on the substrate in an oxygen atmosphere and a room temperature environment of a deposition chamber by using the pulsed laser deposition method.

23. The fabrication method of claim 22, wherein the step S2 comprises:
step S21: depositing and forming the nano-wire film layer on the seed film layer in an oxygen atmosphere of the deposition chamber by using the pulsed laser deposition method.

24. The fabrication method of claim 22, wherein
the step S11 comprises: cleaning the substrate ultrasonically in an acetone solution and an ethanol solution, each for 30-60 minutes.

25. The fabrication method of claim 22, wherein the step S13 comprises: filling oxygen in the vacuum deposition chamber so that the pressure in the deposition chamber would be within a range of 6-10 Pa.

26. The fabrication method of claim 23, wherein the step S21 comprises: filling oxygen in the deposition chamber so that the pressure in the deposition chamber would be within a range of 25-35 Pa.

27. The fabrication method of claim 25, wherein the purity of the filled oxygen is 99.9% to 99.9999%.

28. The fabrication method of claim 26, wherein the purity of the filled oxygen is 99.9% to 99.9999%.

29. The fabrication method of claim 22, wherein in the pulsed laser deposition method, a pulsed laser transmitter is arranged outside the deposition chamber; a focusing lens is arranged between the pulsed laser transmitter and the deposition chamber; the deposition chamber is provided with a transparent quartz window; a target platform and a base platform are arranged oppositely in the deposition chamber; a target material is arranged on the target platform; the focus of the focusing lens, the center of the quartz window and the center of the target material are located in the same straight line; and the substrate is arranged on the base platform and is parallel to the target material,
wherein, the step S13 further comprises: adjusting the distance between the focusing lens and the quartz window to focus the focusing lens on the target material; adjusting the distance between the target material and the substrate to be 4.5-5.5 cm; and setting the target platform and the base platform to rotate at the same rotating speed of 5 r/min.

30. The fabrication method of claim 23, wherein in the pulsed laser deposition method, a pulsed laser transmitter is arranged outside the deposition chamber; a focusing lens is arranged between the pulsed laser transmitter and the deposition chamber; the deposition chamber is provided with a transparent quartz window; a target platform and a base platform are arranged oppositely in the deposition chamber; a target material is arranged on the target platform; the focus of the focusing lens, the center of the quartz window and the center of the target material are located in the same straight line; and the substrate is arranged on the base platform and is parallel to the target material,
wherein, the step S21 further comprises: adjusting the distance between the focusing lens and the quartz window to focus the focusing lens on the target material; adjusting the distance between the target material and the substrate to be 4.5-5.5 cm; and setting the target platform and the base platform to rotate at the same rotating speed of 5 r/min.

31. The fabrication method of claim 29, wherein in the pulsed laser deposition method, the frequency of laser pulses is 9-11 Hz, the number of the laser pulses is 5000-7000, and the energy of a single laser pulses is 248-252 mJ.

32. The fabrication method of claim 29, wherein the target material adopts a transition metal oxide with a purity of 99.99%-99.9999%, and the transition metal oxide comprises zinc oxide, tin oxide or titanium oxide.

33. The fabrication method of claim 30, wherein the target material adopts a transition metal oxide with a purity of 99.99%-99.9999%, and the transition metal oxide comprises zinc oxide, tin oxide or titanium oxide.

34. A transparent conductive film, comprising a seed film layer and a nano-wire film layer, wherein the seed film layer comprises uniformly distributed nano-crystalline grains, the nano-wire film layer comprises a plurality of one-dimensional nano-wires, and the nano-wire film layer is arranged on the seed film layer.

35. The transparent conductive film of claim 44, wherein each one of the plurality of one-dimensional nano-wires extends on the seed film layer in a one-dimensional manner and is arranged in parallel to each other to form the nano-wire film layer, and the diameter of each one of the plurality of one-dimensional nano-wires is 60-80 nm.

36. The transparent conductive film of claim 35, wherein an included angle between each one of the plurality of one-dimensional nano-wires and the seed film layer is 80-90 degrees.

37. The transparent conductive film of claim 34, wherein the seed film layer and the nano-wire film layer are made of a transition metal oxide, and the transition metal oxide comprises zinc oxide, tin oxide or titanium oxide.

38. The transparent conductive film of claim 34, wherein the thickness of the seed film layer is 20-50 nm, and the thickness of the nano-wire film layer is 2-3 μm.

39. A display substrate, comprising the transparent conductive film of claim 34.

40. The display substrate of claim 39, wherein the transparent conductive film is used as a common electrode and/or a pixel electrode of the display substrate.
